(19) United States
(12) Patent Application Publication
(10) Pub. No.: US 2010/0102743 A1
(43) Pub. Date: Apr. 29, 2010

(54) FLEXIBLE LED LIGHTING FILM

(75) Inventors: Wei Hsin Hou, Fremont, CA (US); Robert R. Kimball, Arroyo Grande, CA (US)

Correspondence Address: SINSHEIMER JUHNKE LEBENS & MCIVOR, LLP, 1010 PEACH STREET, P.O. BOX 31, SAN LUIS OBISPO, CA, 93406, US

(73) Assignee: GENERAL LED, INC., A DELAWARE CORPORATION, San Luis Obispo, CA (US)

(21) Appl. No.: 12/260,931

(22) Filed: Oct. 29, 2008

(51) Int. Cl. H05B 37/00; F21V 7/00

(52) U.S. Cl. 315/250; 362/235

(57) ABSTRACT

A lighting unit having a substrate, a light source coupled to the substrate, the light source being configured to generate light. The lighting unit further includes an optical layer positioned over the light source and arranged relative to the substrate to define a region between a top side of the substrate and a bottom side of the optical layer, and a light reflector coupled to the optical layer. The light reflector being structured to reflect at least a portion of the light generated by the light source toward the top side of the substrate, and further structured to define a plurality of light transmissive regions which individually permit transmission of at least a portion of the light generated by the light source.

### BACKGROUND OF THE INVENTION

1. Field of the Invention

The present invention relates generally to light sources, and more specifically to a lighting unit having multiple light sources.

2. Discussion of the Related Art

A light-emitting diode (LED) is an active light source which typically exhibits characteristics such as high efficiency, low power consumption, high brightness and compact volume. A plurality of LEDs can be arranged as an LED array to form a light source, a colored light source, or a white light source by combining red, green, blue or other color LEDs.

One common use of an LED array is to form a backlight unit (BLU) that provides light for a particular application, such as a liquid crystal display (LCD). One type of BLU includes the use of a fluorescent edge light source which operates in conjunction with a waveguide and assorted optical films. Another type of BLU utilizes LEDs as an array light source and function in cooperation with multiple optical films. Yet another type of BLU relates to the use of LEDs as an edge light source which operates in cooperation with a waveguide and multiple optical films.

A common approach for forming an LED array includes use of wire bonding techniques for attaching the LEDs to an underlying substrate. Such wire bonding requires a level of care in order to properly align and place the LEDs during a process known as registration. In addition, consumer demands have driven the need for tighter tolerances, smaller array packages, and decreased fabrication costs.

### SUMMARY OF THE INVENTION

In one embodiment, the invention can be characterized as a lighting unit having a substrate, a light source coupled to the substrate, the light source being configured to generate light. The lighting unit further includes an optical layer positioned over the light source and arranged relative to the substrate to define a region between a top side of the substrate and a bottom side of the optical layer, and a light reflector coupled to the optical layer. The light reflector being structured to reflect at least a portion of the light generated by the light source toward the top side of the substrate, and further structured to define a plurality of light transmissive regions which individually permit transmission of at least a portion of the light generated by the light source.

In yet another embodiment, the invention can be characterized as a lighting unit that includes first and second substrates, a first electrical conductor coupled to the first substrate and configured to receive alternating current (AC) from an AC power source, and a second electrical conductor coupled to the second substrate and configured to receive the AC current from the AC power source. The lighting unit further includes a first group of direct current (DC) light sources electrically coupled to the first electrical conductor and the second electrical conductor, wherein each of the first group of DC light sources is structured to permit current flow in a first direction to generate light, a second group of DC light sources electrically coupled to the first electrical conductor and the second electrical conductor, wherein each of the second group of DC light sources is structured to permit current flow in a second direction to generate light.

### BRIEF DESCRIPTION OF THE DRAWINGS

The above and other aspects, features and advantages of several embodiments of the present invention will be more apparent from the following more particular description thereof, presented in conjunction with the following drawings.

FIG. 1 is a side-view of a portion of a lighting unit in accordance with an embodiment of the present invention.

FIG. 2 is a side-view of a portion of the lighting unit of FIG. 1 during operation in accordance with an embodiment of the present invention.

FIG. 3 is a side-view of a larger portion of the lighting unit of FIG. 1.

FIG. 4 is a top-view of the lighting unit of FIG. 1

FIG. 5 is a detailed top-view of a single reflector region in accordance with an embodiment of the present invention.

FIG. 6 is a side-view of a portion of a lighting unit in accordance with another embodiment of the present invention

FIG. 7 is a side-view of a portion of a lighting unit in accordance with yet another embodiment of the present invention.

FIG. 8 is a side-view of a portion of a lighting unit in accordance with still yet another embodiment of the present invention.

FIG. 9 is a side-view of a portion of a lighting unit in accordance with another embodiment of the present invention.

FIG. 10 is a top-view of the lighting unit of FIG. 1, which is also shown in conjunction with an exemplary power source.

FIG. 11 is a side-view of a portion of a lighting unit in accordance with an embodiment of the present invention

FIG. 12 is side-view of a portion of a lighting unit in accordance with yet another embodiment of the present invention.

FIGS. 13a-13h depict a method of making a lighting device for a lighting unit in accordance with an embodiment of the present invention.

FIGS. 14a-14d depict a light source in accordance with an embodiment of the present invention.

FIGS. 15 and 16 depict portions of a lighting unit in accordance with an embodiment of the present invention.

FIG. 16 is a side-view of a lighting unit with several LEDs positioned between first and second substrates.

FIG. 17 depicts a waveform of alternating current, which may be provided to LEDs via a power source.

FIG. 18 also depicts a waveform of alternating current.

FIGS. 19 and 20 depict light sources in accordance with further embodiments of the present invention.

FIGS. 21a and 21b depict a light source in accordance with yet another embodiment of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

The following description is not to be taken in a limiting sense, but is made merely for the purpose of describing the general principles of exemplary embodiments. The scope of the invention should be determined with reference to the claims.

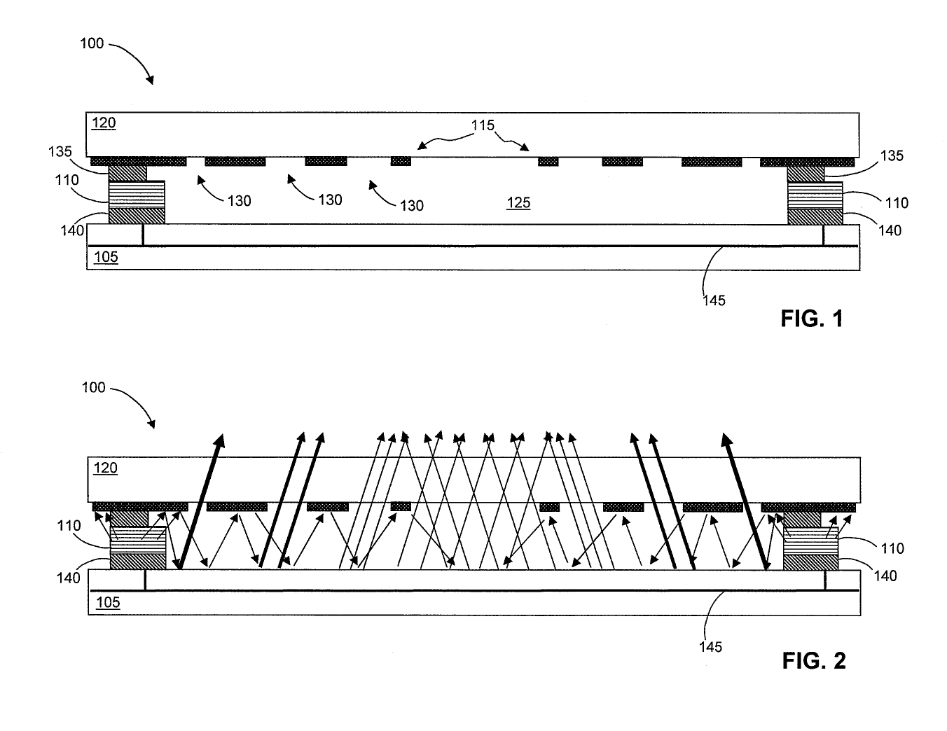

FIG. 1 is a side-view of a portion of a lighting unit in accordance with an embodiment of the present invention. In particular, lighting unit 100 is shown having substrate 105, light emitting diodes (LEDs) 110, and light reflector 115 coupled to optical layer 120. The optical layer and associated light reflector are shown positioned over the LEDs, and may be arranged relative to substrate 105 to define region 125. In this example, region 125 defines an area between a top side of the substrate and a bottom side of the optical layer.

Light reflector 1 15 is typically structured to reflect at least a portion of the light generated by one or more of LEDs 110 toward the top side of substrate 105. In addition, the light reflector may be further structured to define a plurality of light transmissive regions 130 which individually permit transmission of at least a portion of the light generated by the light source. The transmitted light may include light that is directly received from one or more of the LEDs, light reflected from substrate 105, and combinations thereof.

Light reflector 115 may be implemented using any of a variety of different materials which can reflect light. Examples of such materials include metal (e.g., aluminum, gold, silver, nickel, copper, Molybdenum, Chromium), metal alloys, plastic, combinations thereof, and the like. In various embodiments, light reflector 115 also functions as an electrical conductor to supply power to one or more of the LEDs.

LEDs 110 are shown individually coupled to light reflector 115 via electrically conductive adhesive 135, and to substrate 105 via electrically conductive adhesive 140. Adhesive 135 functions to electrically couple a first contact or portion (e.g., p-type semiconductor) of LEDs 110 to light reflector 115, and adhesive 140 functions to electrically couple a second contact or portion (e.g., n-type semiconductor) of LEDs 110 to electrical conductor 145. The LEDs may therefore be powered to generate light responsive to current supplied to reflector 115 and conductor 145.

Adhesives 135, 140 are examples of a technique that may be used to couple associated components such as light reflector 115 and substrate 105. According to alternative embodiments, such adhesives may alternatively or additionally be implemented using any of a variety of different types of bonding materials. Examples of such bonding materials include an eutectic, solder, wave solder, and the like. If desired, the bonding material implemented may be formed as a weld or a wire bond.

LEDs 110 are but one example of a light source that may be implemented in lighting unit 100. Accordingly, the lighting unit may be implemented using various types of light sources including, for example, semiconductor LEDs, electroluminescence (EL), organic LEDs (OLEDs), and the like. Such lighting sources may be AC devices powered via alternating current, DC devices powered via direct current, and DC devices powered via alternating current. The LEDs may be implemented using the same or different colored LEDs (e.g., red, green, blue, white, and the like). For clarity and ease of discussion, various embodiments will be described with regard to light sources implemented using LEDs, but it is understood that such teachings apply equally to other types of light sources.

Substrate 105 may be implemented using assorted materials and structures. In general, the substrate is generally structured to support the light sources of lighting unit 100. In some embodiments, some or all of the top surface of the substrate includes reflective material. In such embodiments, the top side of the substrate is structured to reflect light toward the bottom side of optical layer 120. The reflective material may be in the form of a coating disposed on the substrate, or the reflective material may otherwise be formed within the substrate. The substrate may be formed using a printed circuit board (PCB), a flexible PCB, metal, plastic, paper, and cloth, among others.

Optical layer 120 is generally formed using material which is at least partially light transmissive. An example is to form the optical layer using a substantially transparent film such as polyethylene terephthalate (PET).

Various components (e.g., light reflector 115, adhesives 135, 140, LEDs 110, etc.) of lighting unit 110 are shown having assorted patterns in order to clearly illustrate and distinguish such components. It is understood that these components do not necessarily include such patterns in actual implementations. This understanding applies also for the other lighting units disclosed herein.

FIG. 2 is a side-view of a portion of the lighting unit of FIG. 1 during operation in accordance with an embodiment of the present invention. In this figure, lighting unit 100 is shown generating light from LEDs 110, which is depicted by the arrows leading from the LEDs. At least a portion of the generated light is shown reflected by various portions of light reflector 115, as well as from the top surface of substrate 105. The various arrows also depict reflected light passing through various light transmissive regions 130, and optical layer 120. The thickness of the light arrows represents a possible intensity of the light emitted by lighting unit 100. Although the light transmissive regions permit light rays with different intensities to pass through the optical layer, the overall light distribution of the lighting unit is fairly uniform.

A required or desired light distribution (e.g., uniform) may therefore be achieved by using any of a variety of different techniques. In some embodiments, a particular light distribution may be achieved by varying aperture size, patterns, geometry (e.g., rectangular, circular, oval, triangular, polygonal, etc.), location, number of apertures, and combinations thereof, of various transmissive regions 130. For instance, light reflector 115 may be structured such that aperture size of each of the light transmissive regions 130 is determined or otherwise varied as a function of distance from an associated one of the LEDs 110. Another example includes configuring the light reflector such that aperture size of the light transmissive regions increases or decreases as a function of distance from an associated one of the LEDs.

A further example relates to light reflector 115 being defined by a plurality of reflector regions that are individually associated with one of the LEDs 110. In this example, each of these reflector regions may be structured such that aperture size of the plurality of light transmissive regions located in an associated one of the reflector regions is determined as a function of distance from an associated one of the LEDs.

Some embodiments implement light transmissive regions 103 which are the same or similarly sized. In such embodiments, light reflector 115 may be structured so that the number of light transmissive regions 130 is determined as a function of distance from an associated one of the plurality of light sources. A specific case is one in which the number of such transmissive regions increases or decreases as a function of distance from an associated light source.

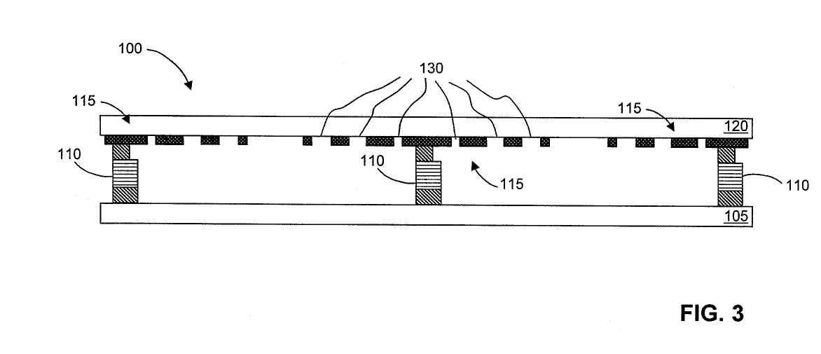

To further illustrate various configurations of light reflector 115, FIG. 3 depicts as a side-view of a greater portion of lighting unit 100 of FIG. 1. In particular, FIG. 3 shows lighting unit 100 having three LEDs 110, which are each positioned relative to associated portions of light reflector 115. In this example, the aperture size of light transmissive regions 130 increases as a function of distance from an associated LED 110 (i.e., the center LED). One alternative is to implement light transmissive regions 130 which are the same or similarly sized. In such an embodiment, the number of light transmissive regions 130 varies (e.g., increases or decreases) as a function of distance from an associated LED 110 (i.e., the center LED). It is understood that some or all of the LEDs of lighting unit 100 may be configured to cooperate with similarly structured light transmissive regions of the light reflector. Portions of substrate 105 have been omitted from this figure for clarity.

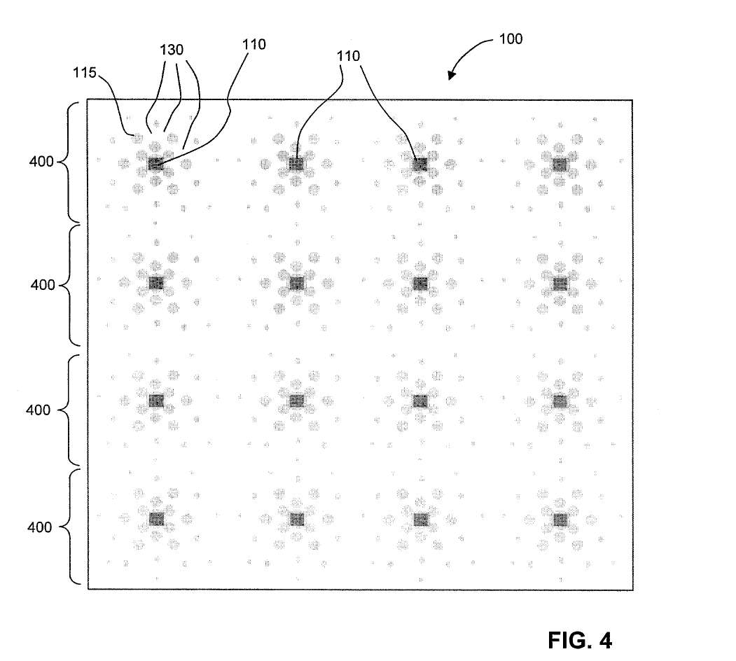

FIG. 4 is a top-view of lighting unit 100 of FIG. 1, and depicts a 4×4 array of LEDs 110 and associated reflector regions 400 of light reflector 115. Similar to FIG. 3, FIG. 4 also shows that the aperture size of light transmissive regions 130 increases as a function of distance from an associated LED 110. The size, shape, and position of light transmissive regions 130 is shown determined by light reflector 115. In general, each LED 110 of lighting unit 100 is associated with a portion of light reflector 115, as denoted by the various LEDs having an associated reflector region 400. In some embodiments, light reflector 115 is implemented as a single component. Other embodiments implement the light reflector as a separate component for one or more LEDs of the lighting unit.

In accordance with further embodiments, lighting unit 100 may be configured with almost any number of LEDs, ranging from as few as one LED to as many as several thousand, or more, LEDs. The LEDs may also be arranged in various arrays and patterns to meet a desired or required arrangement.

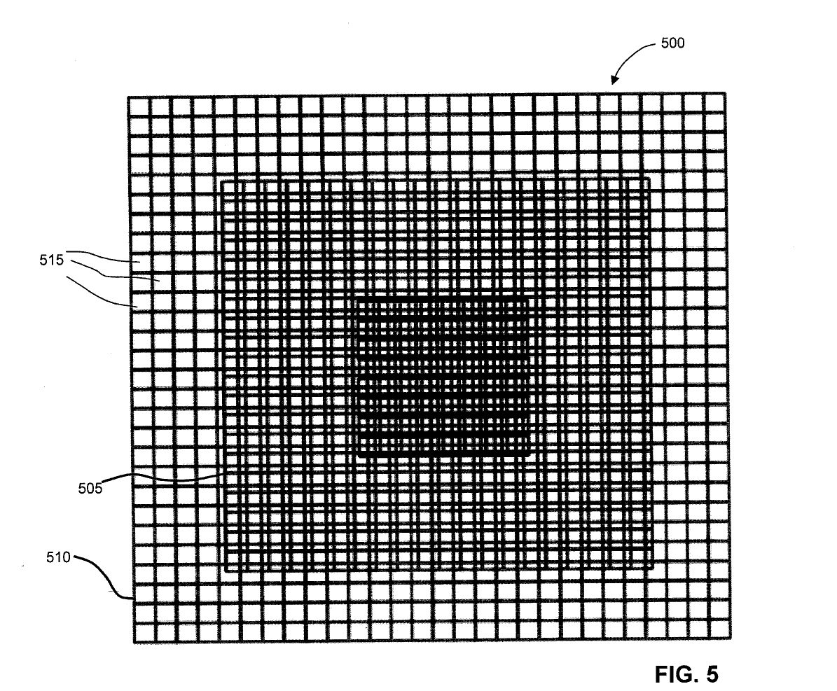

FIG. 5 is a detailed top-view of a single reflector region in accordance with an embodiment of the present invention. In this figure, reflector region 500 is structured as a plurality of offset grids 505, 510, which collectively define a plurality of light transmissive regions 515. In an embodiment, the arrangement of FIG. 5 may replace or augment the structure of any of the light reflectors disclosed herein, including light reflector 115. As an example, light reflector 115 and associated reflector regions 400 (viewable in FIG. 4) may instead be implemented using reflector region 500. If desired, greater or fewer offset grids may alternatively be implemented.

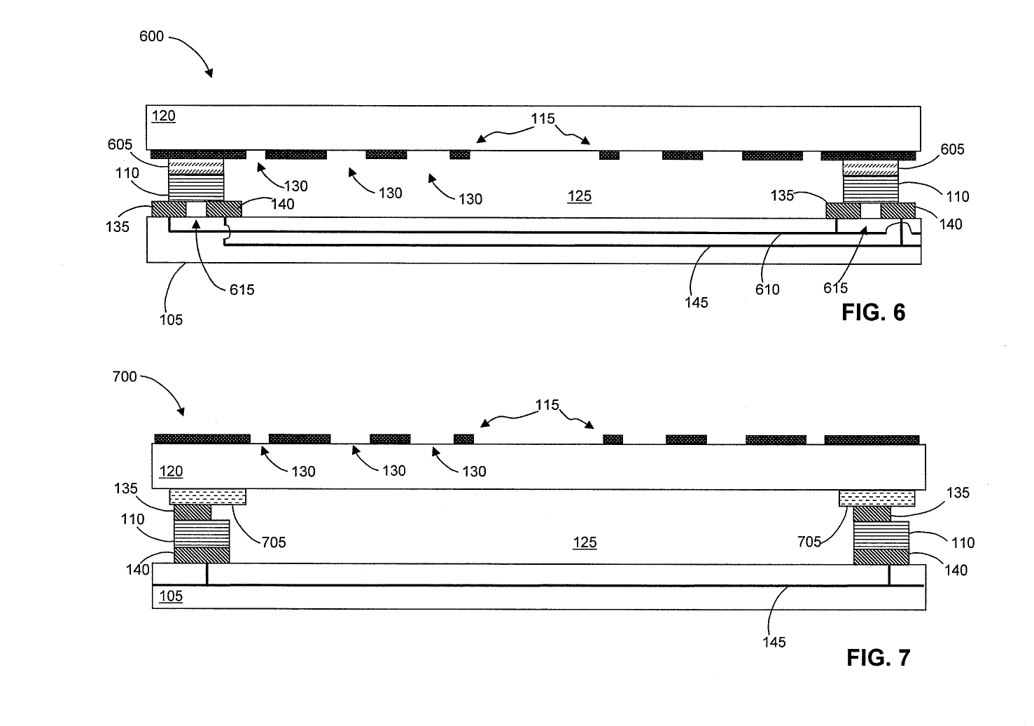

FIG. 6 is a side-view of a portion of a lighting unit in accordance with another embodiment of the present invention. This embodiment is similar to that shown in FIG. 1, but includes several alternative features. For instance, lighting unit 600 includes insulator 605 positioned between one side of light reflector 115 and LED 110. One purpose of the insulator is to electrically insulate LED 110 from the light reflector. The insulator may be implemented using known insulator materials and techniques, and is often at least partially transparent.

In addition, with regard to a second side of light reflector 115, the LEDs of lighting unit 600 are powered to generate light in a manner that differs from that shown in FIG. 1. Specifically, LEDs 110 are shown coupled to substrate 105 via electrically conductive adhesives 135, 140. Adhesive 135 functions to electrically couple a first contact or portion (e.g., p-type semiconductor) of LEDs 110 to electrical conductor 610, and adhesive 140 functions to electrically couple a second contact or portion (e.g., n-type semiconductor) of LEDs 110 to electrical conductor 145. Gap 615 assures electrical isolation between adhesives 135, 140. The LEDs may therefore be powered by applying current to conductors 145, 610.

FIG. 7 is a side-view of a portion of a lighting unit in accordance with yet another embodiment of the present invention. This embodiment is also similar to that shown in FIG. 1, but includes several alternative features. In FIG. 7, lighting unit 700 includes light reflector 115 coupled to the top side of optical layer 120. Lighting unit 700 also includes electrical conductor 705 coupled to the bottom side of optical layer 120. Adhesive 135 is shown coupling conductor 705 to one side, or contact, of an associated LED 110. Conductor 705 may be implemented using a suitable electrical conductor. In some embodiments, the electrical conductor is implemented as an at least partially transparent conducive film (e.g., indium tin oxide (ITO)).

One purpose of electrical conductor 705 is to electrically couple a first contact or portion (e.g., p-type semiconductor) of LEDs 110 to a power source (not shown in this figure). In addition, adhesive 140 functions to electrically couple a second contact or portion (e.g., n-type semiconductor) of LEDs 110 to electrical conductor 145, which is also in communication with the power source.

The lighting unit of FIG. 7 therefore utilizes electrical conductor 705 to power LEDs 110, instead of the light reflector 115. Such arrangement permits, for example, light reflector 115 to be implemented without trace lines which connect to the power source. In addition, the light reflector may also be implemented using non-conductive materials since the light reflector is not needed for supplying current to the LEDs. Electrical conductor 705 may be formed as a pattern which cooperates with the various LEDs, or as a continuous film.

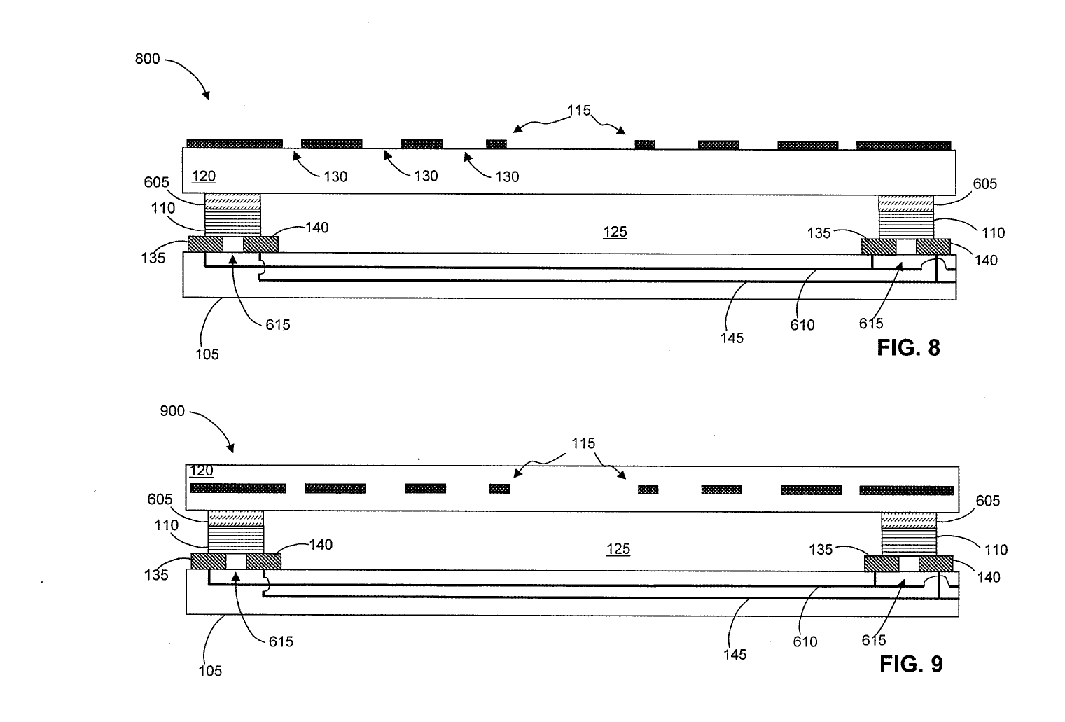

FIG. 8 is a side-view of a portion of a lighting unit in accordance with still yet another embodiment of the present invention. This embodiment generally includes features similar to those shown in both FIG. 6 and FIG. 7. For instance, similar to FIG. 6, lighting unit 800 includes insulator 605 positioned between optical layer 120 and a first side of an associated LED 110. One purpose of the insulator is to electrically insulate LED 110 from the light reflector.

In addition, with regard to a second side of the associated LED 110, lighting unit 800 includes adhesive 135 to electrically couple a first contact or portion (e.g., p-type semiconductor) of LEDs 110 to electrical conductor 610, and adhesive 140 to electrically couple a second contact or portion (e.g., n-type semiconductor) of LEDs 110 to electrical conductor 145. As before, the LEDs may be powered by applying current to conductors 145, 610. Lighting unit 800 also includes light reflector 115 coupled to the top side of optical layer 120. This feature is similar in many respects to that shown in FIG. 7.

FIG. 9 is a side-view of a portion of a lighting unit in accordance with still yet another embodiment of the present invention. In this embodiment, lighting unit 900 is implemented in a manner similar to that shown in FIG. 8, such that the LEDs 110 cooperatively function with conductors 145, 160. One distinction between these lighting units is that lighting unit 900 includes light reflector 115 integrated (e.g. via a lamination process) with optical layer 120.

Since lighting unit 900 utilizes electrical conductors 145, 160 to power LEDs 110, light reflector 115 may therefore be implemented without trace lines which connect to a power source. In addition, the light reflector may also be implemented using non-conductive materials since the light reflector is not needed for supplying current to the LEDs.

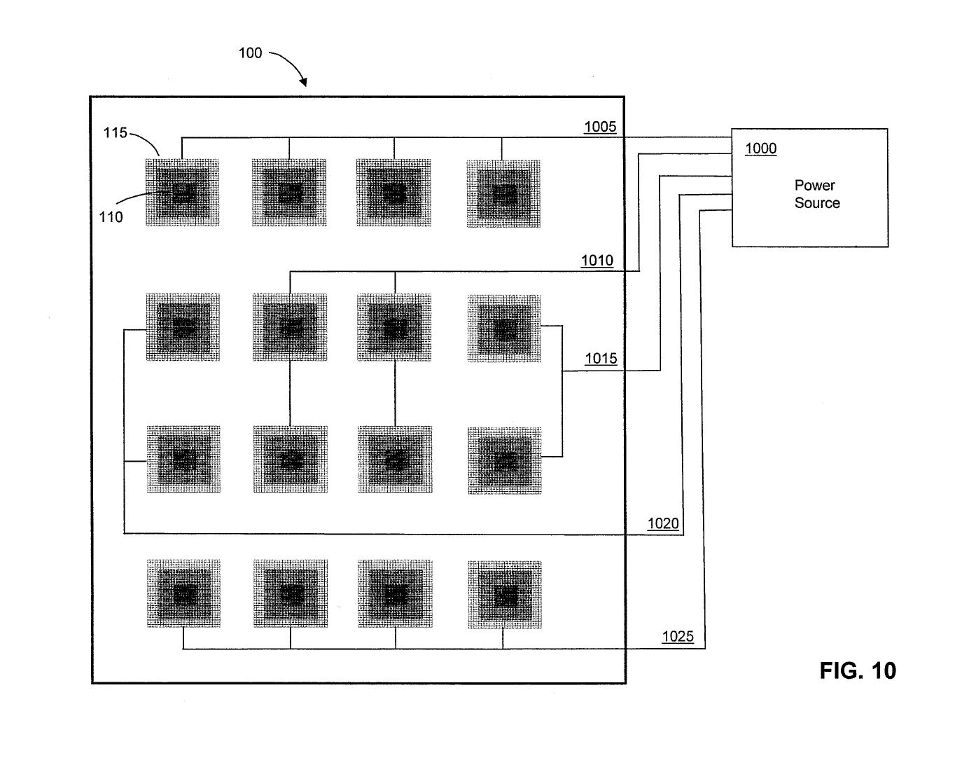

FIG. 10 is a top-view of the lighting unit of FIG. 1, which is also shown in conjunction with an exemplary power source. In FIG. 10, power source 1000 is shown providing power to various LEDs of lighting unit 100, which is implemented using the grid array light reflector depicted in FIG. 5. In this example, power lead 1005 provides power to a top row of LEDs, and power lead 1010 provides power to the center four LEDs. Power leads 1015, 1020, 1025 likewise provide power to associated groupings of LEDs. For clarity, leads 1005-1125 are shown as a single lead. However, such leads are understood as representing both a positive and negative conductive path for their associated LEDs. In an embodiment, portions of the power leads 1005-1125 associated with the light reflector may be implemented using an electrical connector.

As one example, a positive conductive path of lead 1005 may be in electrical communication with electrically conductive light reflector 115 (FIG. 1), and a second conductive path of lead 1005 may be in electrical communication with electrical conductor 145 (FIG. 1). The remaining leads 1005-1025 may be similarly configured with their associated LEDs. The arrangement of FIG. 10 permits control of separate groupings or portions of LEDs of lighting unit 100 by separately controlling power supplied to each of the leads 1005-1025.

Power source 1000 may be implemented using a device or system which can provide power to the various LEDs of the lighting unit. As such, the power source may provide alternating current or direct current. In some embodiments, the power source may be implemented using a stored power device such as a battery.

The arrangement of FIG. 10 is provided to illustrate the cooperation between the components of lighting unit 100 and power source 1000. This arrangement may be modified in any number of ways in accordance with various embodiments of the present invention. Possible modifications include providing additional LEDs and associated light reflectors, arranging the LEDs in different configurations, connecting greater or fewer LEDs, implementing different and varying types of light reflectors, combinations thereof, and the like. It is further understood that power source 1000 may be implemented to supply power to any of the lighting units disclosed herein.

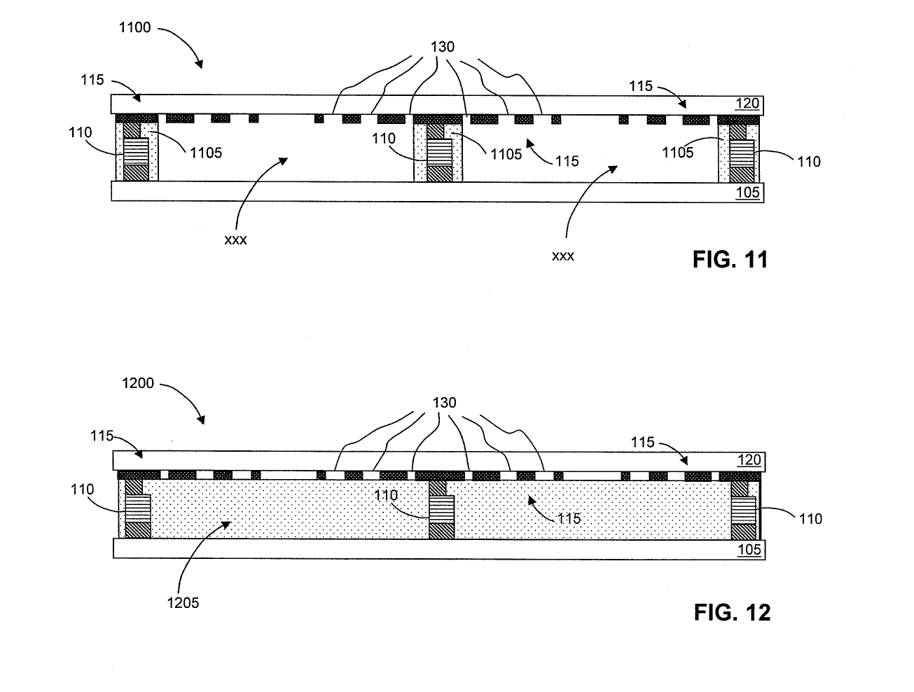

FIG. 11 is a side-view of a portion of a lighting unit in accordance with an embodiment of the present invention. Lighting unit 1100 is similar in many respects to the lighting unit of FIGS. 1 and 3. One difference is that lighting unit 1100 includes spacer material 1105 that is positioned or otherwise located relative to an associated LED 110. The spacer material may be implemented using a resin or adhesive, and is generally partially or substantially light transmissive.

In some embodiments, spacer material 1105 includes a phosphor or other material that is reactive to light generated by one or more of the LEDs 110. A particular example is to include yellow phosphor and to implement one or more of the LEDs 110 using a blue LED. In this arrangement, the blue light from the LED combines with the yellow phosphor, resulting in a substantially white light. Another feature of spacer material 1105 is that it provides an additional degree of support for the associated structures, such as LEDs 110 and optical layer 120, for example.

Since separate spacer material 1105 is located relative to LEDs 110, the spacer material further defines a region between the bottom side of optical layer 120 and the top side of substrate 105. In FIG. 11, this region defines optical free-space region 1110, which is a region that is substantially free of material which affects light transmission.

FIG. 12 is side-view of a portion of a lighting unit in accordance with yet another embodiment of the present invention, and is similar in many respects to the lighting unit of FIG. 11. A difference between these lighting units relates to lighting unit 1200 implementing spacer material 1205 within all, or substantially all, of the region between the bottom side of optical layer 120 and the top side of substrate 105. Lighting unit 1200 is not shown with a optical free-space region as is the case in FIG. 11. Spacer material 1205 may be implemented using the same or similar materials as used for spacer material 105 of FIG. 11.

The relatively greater portions of spacer material 1205 provide an assortment of potential benefits. For instance, the depicted arrangement provides for additional structural support for surrounding components. Moreover, the greater quantities of spacer material allows for the introduction of greater amounts of additional materials, such as reflective participles, light-reactive phosphors, and the like. In accordance with other embodiments, use of the spacer material in FIGS. 11 and 12 may be similarly implemented in any of the other lighting units disclosed herein. Note also that for clarity, the conductors of substrate 105 have been omitted from FIGS. 11 and 12.

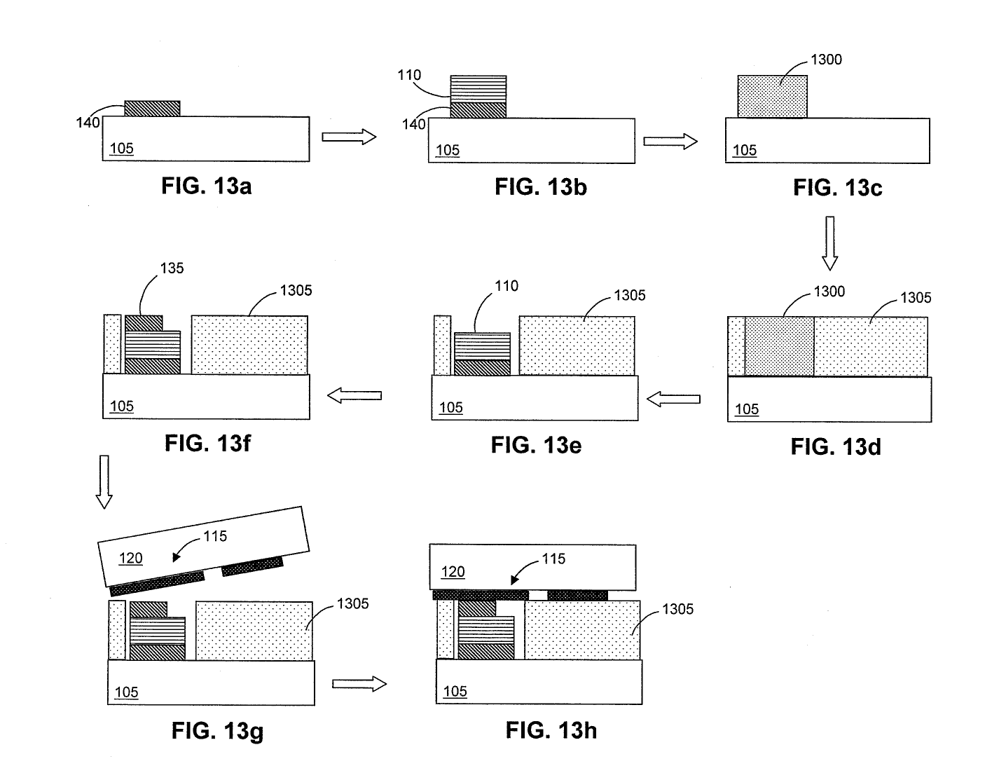

FIGS. 13a-13h depict a method of making a lighting device for a lighting unit in accordance with an embodiment of the present invention. One operation includes coupling a light source, such as LED 110, to substrate 105. This operation may be accomplished by providing conductive adhesive 140 on the substrate (FIG. 13a), and then coupling LED 110 to the adhesive. Another operation includes covering the LED with liftoff material 1300 (FIG. 13c). One purpose for the lift-off is to protect the underlying structures (e.g., LED 110, adhesive 140) from materials that are later formed over the lighting unit.

FIG. 13d depicts an optional feature of providing spacer 1305 over substrate 105. Spacer 1305 may be implemented using any of the spacer materials previously described. FIG. 13e shows removing the liftoff material to expose the underling structure, such as light source 110. FIG. 13f shows an optional operation in which adhesive 135 is located on LED 110.

FIG. 13g includes coupling light reflector 115 to optical layer 120. Recall that the light reflector may be structured to reflect at least a portion of the light generated by LED 110 toward a top side of substrate 105, and is also structured to define a plurality of light transmissive regions which individually permit transmission of at least a portion of the light generated by the LED.

FIG. 13h depicts positioning optical layer 120 over LED 110 to define a region within which spacer 1305 is located. If desired, reflective material may be located relative (e.g., above, disposed over, integrated within, etc.) to the top side of substrate 105.

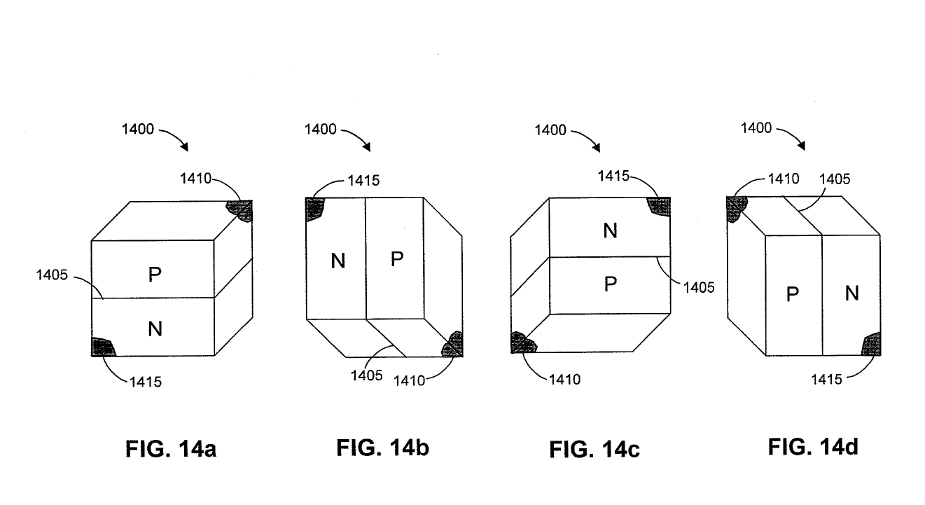

FIGS. 14a-14d depict a light source in accordance with an embodiment of the present invention. In general, LEDs 1400 may be implemented using any of the lighting sources disclosed herein, including AC lighting sources, DC lighting sources, LEDs. OLEDs, and the like. In FIG. 14a, a light source is shown configured as LED 1400 having a p-type region and an n-type region. These regions abut each other at p-n junction 1405. Current flowing from the p-type region to the n-type region causes the release of energy resulting in the generation of light at the p-n junction.

In accordance with various embodiments, LED 1400 includes first contact 1410 located along a corner of the p-type region, and second contact 1415 along a corner of the n-type region. As will be described in later figures, the first and second contacts are structured to permit coupling to a suitable power source to permit powering of the LED.

FIGS. 14a-14d show LED 1440 as it is rotated clockwise, which illustrates the positioning of the first and second contacts 1410, 1415. In general, first and second contacts 1410, 1415 may each be formed along a plurality of substantially planar surfaces. In this example, the plurality of substantially planar surfaces associated with first contact 1410 are arranged to define a first corner, and the plurality of substantially planar surfaces associated with second contact 1410 are arranged to define a second corner. In an embodiment, the first corner opposes the second corner for each of these LEDs.

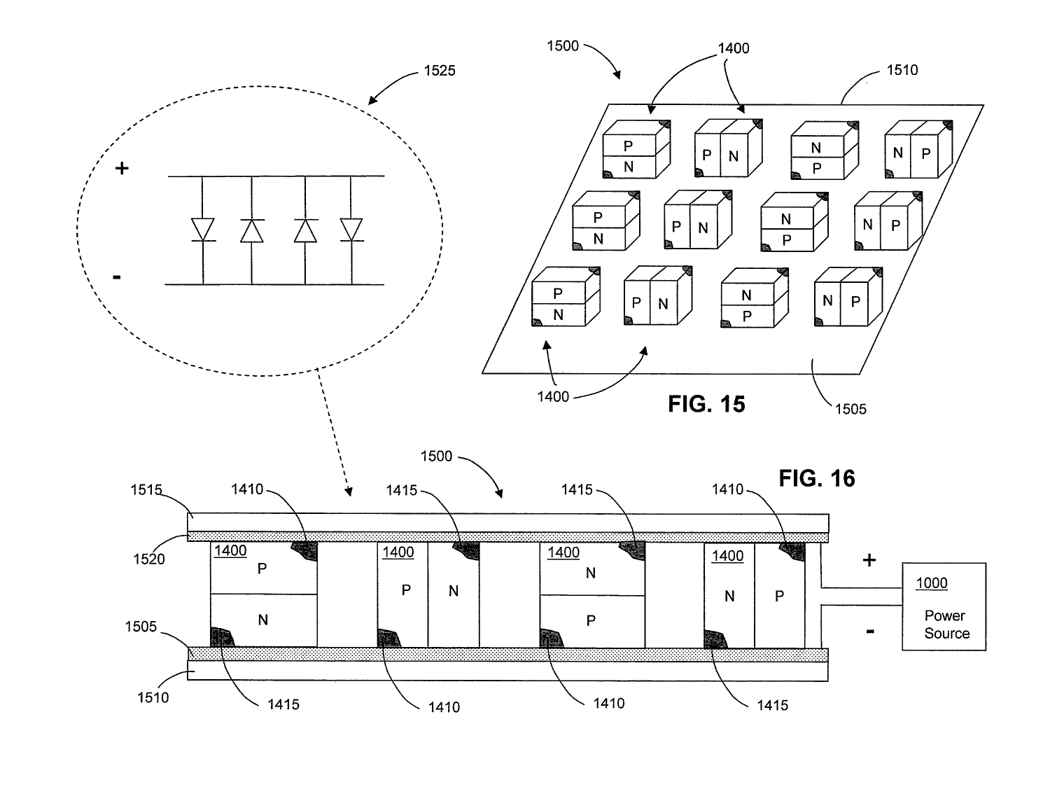

FIGS. 15 and 16 depict portions of a lighting unit in accordance with an alternative embodiment of the present invention. More specifically, FIG. 15 shows lighting unit 1500 having various LEDs 1400 located upon a first electrical conductor 1505 that is coupled to first substrate 1510. The top substrate has been omitted to permit viewing of the various LEDs.

FIG. 16 is a side-view of lighting unit 1500 and depicts several LEDs 1400 positioned between first substrate 1510 and second substrate 1515. First electrical conductor 1505 is shown coupled to first substrate 1510, and second electrical conductor 1520 is shown coupled to second substrate 1515. Power source 1000 provides power to LEDs 1400 via conductors 1505, 1520 and the first and second contacts 1410, 1415 associated with each of the LEDs. Substrates 1510, 1515 may be implemented using any of the materials used to form the substrate and optical layers previously described. In addition, the number and configuration of the LEDs 1400 may also be implemented using any of the techniques previously described. Circuit 1525 is representative of a circuit that may be used to implement the four LEDs 1400 shown in FIG. 16.

In an embodiment, LEDs 1400 are each implemented as a direct current (DC) light source which is powered by alternating current provided by power source 1000. Conductor 1520 is shown connected to the positive side of power source 1000, and conductor 1505 is shown connected to the negative side of the power source.

The LEDs shown in FIGS. 15 and 16 may be defined as two groups of LEDs, such that one group is structured to permit current flow in a first direction to generate light, and a second group is structure to permit current flow in a second direction to generate light. In FIG. 16, the right-most and left-most LEDs 1400 permit current flow in one direction such that these LEDs have a first contact 1410 that couples with the positive side of the power source via conductor 1520, and a second contact 1415 that couples with the negative side of the power source via conductor 1505.

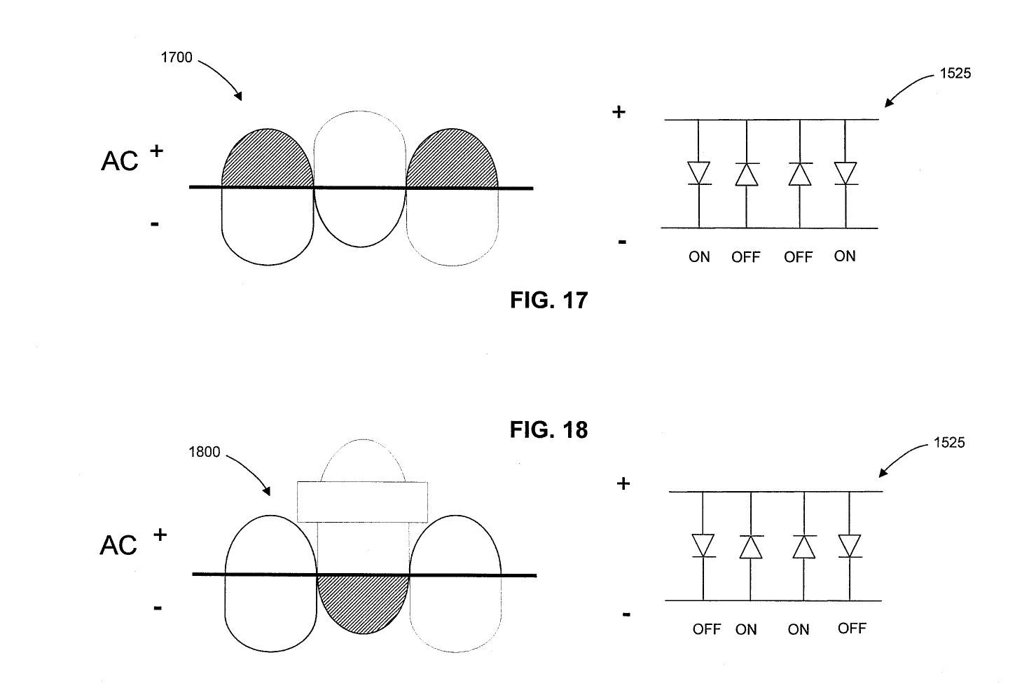

The center-two LEDs 1400 have the opposite arrangement such that these LEDs permit current flow in the opposite direction since these LEDs have a first contact 1410 that couples with the negative side of the power source via conductor 1505 and a second contact 1415 that couples with the positive side of the power source via conductor 1520. Operation of the embodiment of FIG. 16 will now be described with additional reference to FIGS. 17 and 18.

FIG. 17 depicts waveform 1700 of alternating current, which may be provided to LEDs via power source 1000. During the high (positive) cycle of this waveform, the LEDs of lighting unit 1500 will behave as depicted in circuit 1525 (FIG. 17). Specifically, the first group of LEDs (the right-most and the left-most LEDs) permit adequate current flow during the positive portion of the cycle and will consequently generate light during these periods of the cycle. The opposite is the case for the second group of LEDs (the center-two LEDs), such that these LEDs do not permit adequate current flow during the positive portion of the cycle, and thus, do not generate light during these time periods.

FIG. 18 also depicts waveform 1800 of alternating current. During the low or negative cycle depicted in this waveform, the LEDs of lighting unit 1500 will behave as depicted in circuit 1525 (FIG. 18). According to this circuit, the second group of LEDs (the inner-two LEDs) permit adequate current flow during the negative portion of the cycle and will consequently generate light during these time periods. Conversely, the first group of LEDs (right-most and the left-most LEDs) do not permit adequate current flow during the negative portion of the cycle, and thus, do not generate light during these time periods. The forgoing illustrates the scenario during which the effective powering of the LEDs in order to generate light will alternate in accordance with the positive and negative cycles of the received current.

Each of the LEDs of lighting unit 1500, such as those depicted in FIG. 15, may be powered to light in accordance with the just-described technique. It is not a requirement that the LEDs 1400 be located with any particular orientation. Because contacts 1410, 1415 are located on opposing corners of an associated LED 1400, the LED can be powered regardless of the orientation at which the LED is placed between the conductors 1505, 1520.

It is understood that at any given time, a percentage of the LEDs of lighting unit 1500 will not be generating light. Such a potential drawback can be minimized, or effectively eliminated, by implementing sufficient numbers of LEDs in the lighting unit.

A number of potential advantages may be achieved using the depicted arrangement of lighting unit 1500. First, a lighting unit may be formed using a low-cost printing process, for example, to place or otherwise locate the LEDs. This is because the LEDs can be powered regardless of their orientation relative to the first and second conductors 1505, 1520. In addition, such placement does not require costly and time-consuming precision registration. Further, lighting unit 1500 may be implemented using DC LEDs as a light source, which are significantly cheaper than AC LEDs. Still further, the lighting unit can be directly coupled to an AC power source, without the need for a transformer to convert the AC into direct current.

According to FIGS. 15 and 16, each of the first group of LEDs 1900 (the left-most and right-most LEDs) is positioned so that a region of first contact 1410 formed along only one of a plurality of substantially planar surfaces is structured to physically couple or otherwise communicate with the first conductor 1520. That is, even though first contact 1410 is located on multiple sides of the LED, only one region or side of the first contact physically couples with first conductor 1520. Second contact 1415 of the first group of LEDs may be similarly configured.

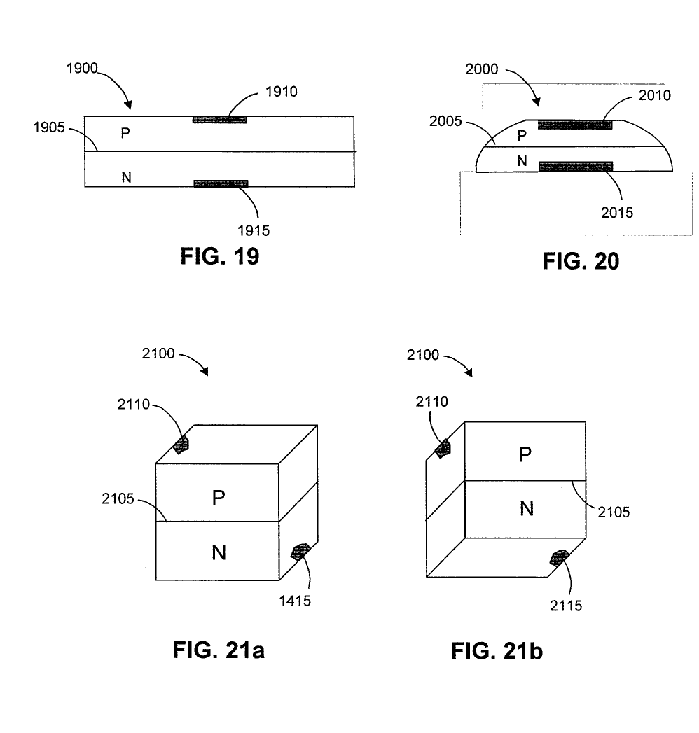

FIGS. 19 and 20 depict light sources in accordance with further embodiments of the present invention. In FIG. 19, a light source is shown configured as LED 1900 having a p-type region and an n-type region. These regions abut each other at p-n junction 1905. Current flowing from p-type region to the n-type region causes the release of energy resulting the generation of light at the p-n junction.

In accordance with various embodiments, LED 1900 includes first contact 1910 located a top surface of p-type region, and second contact 1915 along a top surface of the n-type region. The first and second contacts are structured to permit coupling to a suitable power source to permit powering of the LED. In general, the top surfaces of the p-type region and the n-type regions are substantially planar. Note also that LED 1900 has a length that is greater than its height. A potential benefit of this configuration is that it permits the LED to be readily positioned over a substrate in one of two orientations; namely, the p-type region over the n-type region, or vice-versa. LEDs that are positioned on either end can be easily identified and either removed or repositioned so that they are orientated correctly.

LED 1900 may be implemented in any of the lighting units disclosed herein, including lighting unit 1500 of FIGS. 15 and 16. When LED 1900 is implemented as a DC LED powered by alternating current, LED 1900 functions to provide light in a manner similar to that of LEDs 1400.

In FIG. 20, LED 2000 has many of the same characteristics of LED 1900. One difference between these LEDs is that LED 2000 includes curved sides, which contrasts the substantially planar sides LED 1900. The curved sides of LED 2000 facilitate placement of the LED over a substrate (e.g., substrate 1510 and included conductor 1505). Should LED 2000 be initially placed on its side, the curved nature of the side will tend to cause the LED to fall so that it rests with one of the top portions contacting the surface of the conductor or substrate.

FIGS. 21a and 21b depict a light source in accordance with yet another embodiment of the present invention. These figures depict a light source implemented as an LED structured as a cube. As an example, LED 2100 includes a p-type region and an n-type region, with an associated p-n junction 2105.

In accordance with various embodiments, LED 2100 includes first contact 2110 located along a top and side surface of the p-type region, and second contact 2115 along a top and side surface of the n-type region. The first and second contacts are structured to permit coupling to a suitable power source to permit powering of the LED.

FIG. 21a shows first contact 2110 along a top side of the p-type region, and second contact 2115 along a right side of the n-type region. FIG. 21b provides a further illustration looking toward the bottom-left side of LED 2105. In FIG. 21b, first contact 2110 is visible on the left side of the p-type region, and second contact 2115 is visible on the bottom side of the n-type region.

LED 2100 is shown as a cube defined by a plurality of substantially planar surfaces. First contact 2110 is defined by two surfaces which lie in planes that are approximately 90 degrees relative to one another, such that the first contact has one surface along the top side (FIG. 21a) and a second surface along the left side (FIG. 21b). Second contact 2115 is likewise defined by two surfaces which lie in planes that are approximately 90 degrees relative to one another, such that the second contact has one surface along the right side (FIG. 21a) and a second surface along the bottom side (FIG. 21b).

In an embodiment, the first and second contacts are on opposing edges of the LED. If desired, the first contact 2110 may be located along any of the edges of the p-type region, and second contact 2115 may likewise be located along any of the edges of the n-type region.

In general, the various LEDs of FIGS. 19, 20, and 21 a may be implemented using any of the light sources disclosed herein, including AC light sources, DC light sources, LEDs, OLEDs, and the like. In addition, such LEDs may be used as light sources in any of the lighting units disclosed herein.

The various lighting systems and light sources that have been described may be implemented in assorted systems and applications in accordance with embodiments of the present invention. An example of such embodiments includes use as a backlighting unit, an LED display, an LCD display, and the like.

What is claimed is:

1. A lighting unit, comprising:
a substrate;
a light source coupled to the substrate, the light source being configured to generate light;
an optical layer positioned over the light source and arranged relative to the substrate to define a region between a top side of the substrate and a bottom side of the optical layer; and
a light reflector coupled to the optical layer, the light reflector being structured to reflect at least a portion of the light generated by the light source toward the top side of the substrate, and further structured to define a plurality of light transmissive regions which individually permit transmission of at least a portion of the light generated by the light source.

2. The lighting unit of claim 1, further comprising:
a plurality of light sources coupled to the substrate, each of the plurality of light sources being configured to generate light.

3. The lighting unit of claim 2, wherein the light reflector is structured such that aperture size of each of the plurality of light transmissive regions is determined as a function of distance from an associated one of the plurality of light sources.

4. The lighting unit of claim 2, wherein the light reflector is structured such that aperture size of each of the plurality of light transmissive regions increases as a function of distance from an associated one of the plurality of light sources.

5. The lighting unit of claim 2, wherein the light reflector is structured, for each of the plurality of light sources, as a plurality of offset grids which define the plurality of light transmissive regions as a grid array of light transmissive regions.

6. The lighting unit of claim 2, wherein the light reflector is defined by a plurality of reflector regions individually associated with one of the plurality of light sources, wherein each of the plurality of reflector regions is structured such that aperture size of the plurality of light transmissive regions located in an associated one of the plurality of reflector regions is determined as a function of distance from an associated one of the plurality of light sources.

7. The lighting unit of claim 2, wherein the light reflector is structured such that a number of the plurality of light transmissive regions is determined as a function of distance from an associated one of the plurality of light sources.

8. The lighting unit of claim 2, wherein the light reflector is structured such that a number of the plurality of light transmissive regions increases as a function of distance from an associated one of the plurality of light sources.

9. The lighting unit of claim 2, wherein the light reflector is defined by a plurality of reflector regions individually associated with one of the plurality of light sources, wherein each of the plurality of reflector regions is structured such that a number of the plurality of light transmissive regions located in an associated one of the plurality of reflector regions is determined as a function of distance from an associated one of the plurality of light sources.

10. The lighting unit of claim 2, further comprising:
for each of the plurality of light sources, a first electrically conductive bonding material positioned to couple the light reflector to an associated one of the plurality of light sources; and
for each of the plurality of light sources, a second electrically conductive bonding material positioned to couple an electrical conductor of the substrate to the associated one of the plurality of light sources.

11. The lighting unit of claim 10, wherein
the first electrically conductive bonding material is a material selected from the group consisting of an adhesive, an eutectic, a solder, and wave solder; and wherein
the second electrically conductive bonding material is a material selected from the group consisting of an adhesive, an eutectic, a solder, and wave solder.

12. The lighting unit of claim 10, wherein
the first electrically conductive bonding material is formed as a weld; and wherein
the second electrically conductive bonding material is formed as a weld.

13. The lighting unit of claim 10, wherein
the first electrically conductive bonding material is formed as a wire bond; and wherein
the second electrically conductive bonding material is formed as a wire bond.

14. The lighting unit of claim 2, further comprising:
for each of the plurality of light sources, an insulator positioned between the light reflector and a first side of an associated one of the plurality of light sources; and
for each of the plurality of light sources, a first electrically conductive bonding material positioned to couple a first electrical conductor of the substrate with a first portion of a second side of the associated one of the plurality of light sources, and a second electrically conductive bonding material positioned to couple a second electrical conductor of the substrate with a second portion of the second side of the associated one of the plurality of light sources.

15. The lighting unit of claim 14, wherein
the first electrically conductive bonding material is a material selected from the group consisting of an adhesive, an eutectic, a solder, and wave solder; and wherein
the second electrically conductive bonding material is a material selected from the group consisting of an adhesive, an eutectic, a solder, and wave solder.

16. The lighting unit of claim 14, wherein
the first electrically conductive bonding material is formed as a weld; and wherein
the second electrically conductive bonding material is formed as a weld.

17. The lighting unit of claim 14, wherein
the first electrically conductive bonding material is formed as a wire bond; and wherein
the second electrically conductive bonding material is formed as a wire bond.

18. The lighting unit of claim 2, further comprising:
a first electrical conductor coupled to the bottom side of the optical layer;
a second electrical conductor located relative to the substrate;
for each of the plurality of light sources, a first electrically conductive bonding material for coupling the first electrical conductor to a first contact of an associated one of the plurality of light sources; and
for each of the plurality of light sources, a second electrically conductive bonding material for coupling the second electrical conductor to a second contact of an associated one of the plurality of light sources.

19. The lighting unit of claim 18, wherein
the first electrically conductive bonding material is a material selected from the group consisting of an adhesive, an eutectic, a solder, and wave solder; and wherein
the second electrically conductive bonding material is a material selected from the group consisting of an adhesive, an eutectic, a solder, and wave solder.

20. The lighting unit of claim 18, wherein
the first electrically conductive bonding material is formed as a weld; and wherein
the second electrically conductive bonding material is formed as a weld.

21. The lighting unit of claim 18, wherein
the first electrically conductive bonding material is formed as a wire bond; and wherein
the second electrically conductive bonding material is formed as a wire bond.

22. The lighting unit of claim 18, wherein the light reflector is coupled to a top side of the optical layer.

23. The lighting unit of claim 2, further comprising:
for each of the plurality of light sources, an insulator positioned between the optical layer and a first side of an associated one of the plurality of light sources; and
for each of the plurality of light sources, a first electrically conductive bonding material positioned to couple a first electrical conductor of the substrate with a first portion of a second side of the associated one of the plurality of light sources, and a second electrically conductive bonding material positioned to couple a second electrical conductor of the substrate with a second portion of the second side of the associated one of the plurality of light sources.

24. The lighting unit of claim 23, wherein
the first electrically conductive bonding material is a material selected from the group consisting of an adhesive, an eutectic, a solder, and wave solder; and wherein
the second electrically conductive bonding material is a material selected from the group consisting of an adhesive, an eutectic, a solder, and wave solder.

25. The lighting unit of claim 23, wherein
the first electrically conductive bonding material is formed as a weld; and wherein
the second electrically conductive bonding material is formed as a weld.

26. The lighting unit of claim 23, wherein
the first electrically conductive bonding material is formed as a wire bond; and wherein
the second electrically conductive bonding material is formed as a wire bond.

27. The lighting unit of claim 23, wherein the light reflector is coupled to a top side of the optical layer.

28. The lighting unit of claim 2, wherein:
each of the plurality of light sources comprise a light emitting diode (LED) that includes a first contact and a second contact, the first contact being electrically coupled to the light reflector and the second contact being electrically coupled to an electrical conductor of the substrate; and wherein
each of the plurality of light sources is configured to generate the light responsive to current supplied to the light reflector and the electrical conductor of the substrate.

29. The lighting unit of claim 2, wherein:
each of the plurality of light sources comprise a light emitting diode (LED) that includes a first contact and a second contact, the first contact being electrically coupled to a first electrical conductor of the substrate and the second contact being electrically coupled to an second electrical conductor of the substrate; and wherein
each of the plurality of light sources is configured to generate the light responsive to current supplied to the first electrical conductor and the second electrical conductor.

30. The lighting unit of claim 2, further comprising:
a plurality of light reflectors coupled to the optical layer, wherein each of the plurality of light reflectors is structured to reflect at least a portion of the light generated by an associated one of the plurality of light sources toward the top side of the substrate, and further structured to define a plurality of light transmissive regions which individually permit transmission of at least a portion of the light generated by the associated one of the plurality of light sources.

31. The lighting unit of claim 30, further comprising:
an electrical connector configured to electrically connect some of the plurality of light reflectors.

32. The lighting unit of claim 30, further comprising:
an electrical connector configured to electrically connect all of the plurality of light reflectors.

33. The lighting unit of claim 1, further comprising:
spacer material substantially light transmissive, and located between the top side of the substrate and the bottom side of the optical layer.

34. The lighting unit of claim 2, further comprising:
spacer material located between the top side of the substrate and the bottom side of the optical layer, wherein the spacer material comprises a phosphor reactive to the light generated by at least one of the plurality of light sources.

35. The lighting unit of claim 2, further comprising:
separate spacer material located relative to each of the plurality of light sources and which further defines the region as including an optical free-space region.

36. The lighting unit of claim 1, wherein the substrate comprises reflective material.

37. The lighting unit of claim 1, further comprising:
reflective material disposed on the substrate.

38. The lighting unit of claim 1, wherein the top side of the substrate is structured to reflect light toward the bottom side of the optical layer.

39. The lighting unit of claim 2, wherein each of the plurality of light sources comprises a light emitting diode (LED).

40. The lighting unit of claim 1, wherein the plurality of light transmissive regions and structured to individually permit transmission of light reflected from the top side of the substrate.

41. The lighting unit of claim 1, wherein the light reflector is coupled to the bottom side of the optical layer.

42. The lighting unit of claim 1, wherein the optical layer is at least partially light transmissive.

43. The lighting unit of claim 1, wherein the light reflector is integrated with the optical layer.

44. A lighting unit, comprising:
a first substrate;
a first electrical conductor coupled to the first substrate and configured to receive alternating current (AC) from an AC power source;
a second substrate;
a second electrical conductor coupled to the second substrate and configured to receive the AC current from the AC power source;
a first group of direct current (DC) light sources electrically coupled to the first electrical conductor and the second electrical conductor, wherein each of the first group of DC light sources is structured to permit current flow in a first direction to generate light; and
a second group of DC light sources electrically coupled to the first electrical conductor and the second electrical conductor, wherein each of the second group of DC light sources is structured to permit current flow in a second direction to generate light.

45. The lighting unit according to claim 44, wherein
each of the first group of DC light sources comprises a first contact formed along a plurality of substantially planar surfaces, and wherein each of the first group of DC light sources is positioned so that a region of the first contact that is formed along only one of the plurality of substantially planar surfaces is structured to physically couple with the first electrical conductor; wherein
each of the first group of DC light sources comprises a second contact formed along a plurality of substantially planar surfaces, and wherein each of the first group of DC light sources is positioned so that a region of the second contact that is formed along only one of the plurality of substantially planar surfaces is structured to physically couple with the second electrical conductor; wherein
each of the second group of DC light sources comprises a first contact formed along a plurality of substantially planar surfaces, and wherein each of the second group of DC light sources is positioned so that a region of the first contact that is formed along only one of the plurality of substantially planar surfaces is structured to physically couple with the first electrical conductor; and wherein
each of the second group of DC light sources comprises a second contact formed along a plurality of substantially planar surfaces, and wherein each of the second group of DC light sources is positioned so that a region of the second contact that is formed along only one of the plurality of substantially planar surfaces is structured to physically couple with the second electrical conductor.

46. The lighting unit according to claim 45, further comprising:
for each of the first group of DC light sources, the plurality of substantially planar surfaces associated with the first contact are arranged to define a first corner, and the plurality of substantially planar surfaces associated with the second contact are arranged to define a second corner, and
for each of the second group of DC light sources, the plurality of substantially planar surfaces associated with the first contact are arranged to define a first corner, and the plurality of substantially planar surfaces associated with the second contact are arranged to define a second corner.

47. The lighting unit according to claim 46, further comprising:
for each of the first group of DC light sources, the first corner opposes the second corner, and wherein
for each of the second group of DC light sources, the first corner opposes the second corner.

48. The lighting unit according to claim 44, further comprising:
for each of the first group of DC light sources, the plurality of substantially planar surfaces associated with the first contact define two surfaces which lie in planes that are approximately 90 degrees relative to one another; and wherein the plurality of substantially planar surfaces associated with the second contact define two surfaces which lie in planes that are approximately 90 degrees relative to one another; and
for each of the second group of DC light sources, the plurality of substantially planar surfaces associated with the first contact define two surfaces which lie in planes that are approximately 90 degrees relative to one another; and wherein the plurality of substantially planar surfaces associated with the second contact define two surfaces which lie in planes that are approximately 90 degrees relative to one another.

49. The lighting unit according to claim 44, wherein
each of the first group of DC light sources comprises a first substantially planar surface which includes a first contact structured to communicate with the first electrical conductor, and a second substantially planar surface which includes a second contact structured to communicate with the second electrical conductor; and wherein
each of the second group of DC light sources comprises a first substantially planar surface which includes a first contact structured to communicate with the first electrical conductor, and a second substantially planar surface which includes a second contact structured to communicate with the second electrical conductor.

50. The lighting unit according to claim 44, wherein the first direction is opposite that of the second direction.

51. The lighting unit according to claim 44, wherein each of the plurality of light sources comprises a light emitting diode (LED).
